(19) United States
(12) Patent Application Publication
(10) Pub. No.: US 2005/0201139 A1
(43) Pub. Date: Sep. 15, 2005

(54) Memory Device

(75) Inventors: Yasuhiro Shimada, Kyoto (JP); Yoshihisa Kato, Shiga (JP); Keisuke Tanaka, Kyoto (JP); Daisuke Ueda, Osaka (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd., Osaka (JP)

(21) Appl. No.: 11/121,011

(22) Filed: May 4, 2005

Related U.S. Application Data
(62) Division of application No. 10/601,558, filed on Jun. 24, 2003.

(30) Foreign Application Priority Data
Jun. 27, 2002 (JP) 2002-187222

(51) Int. Cl. G11C 11/22

(52) U.S. Cl. 365/145

(57) ABSTRACT

A memory device includes memory cells each having a capacitor including a lower electrode, a ferroelectric film and an upper electrode which are formed in this order over a substrate made of silicon. The ferroelectric film is selectively grown on the lower electrode. Such selective formation of the ferroelectric film on the lower electrode having a desired shape prevents a damaged portion from occurring in the ferroelectric film, thus making it possible to downsize the memory cells.

### BACKGROUND OF THE INVENTION

The present invention relates to memory devices whose memory cells include capacitors using capacitive films made of ferroelectrics.

FIG. 5 shows a known memory device in which each memory cell is made of a capacitor using a ferroelectric for its capacitive film and a selective transistor selectively making the capacitor accessible. As shown in FIG. 5, one electrode of a ferroelectric capacitor 101 is connected to the source of a selective transistor 102 and the other electrode is connected to a cell plate line CP. The drain of the selective transistor 102 is connected to a bit line BL and the gate thereof is connected to a word line WL.

FIG. 6 shows an example of a cross-sectional structure of a memory cell having such a circuit configuration. As shown in FIG. 6, the selective transistor 102 includes: drain and source regions 111 and 112 formed in an upper portion of a silicon substrate 110 to be spaced from each other; and a gate electrode 114 formed over the substrate 110 and covered with a first insulating layer 113.

The ferroelectric capacitor 101 is formed on the first insulating layer 113 and over the source region 112 and includes a first electrode 115, a ferroelectric film 116 and a second electrode 117.

The first electrode 115 of the ferroelectric capacitor 101 is electrically connected to the source region 112 of the selective transistor 102 via a first contact plug 118 provided through the first insulating layer 113. The second electrode 117 of the ferroelectric capacitor 101 is connected to a cell plate line CP.

A second insulating layer 119 is formed on the first insulating layer 113 to cover the ferroelectric capacitor 101. A third insulating layer 120 is formed on the second insulating layer 119 to cover the cell plate line CP.

A bit line BL is provided on the third insulating layer 120 and over the drain region 111. The bit line BL is electrically connected to the drain region 111 via a second contact plug 121 formed through the first, second and third insulating layers 113, 119 and 120.

FIGS. 7A through 7C schematically show respective process steps of a method for forming the ferroelectric capacitor 101. In FIGS. 7A through 7C, the selective transistor 102 is omitted.

First, as shown in FIG. 7A, a first electrode film 115A, a ferroelectric film 116 and a second electrode film 117A are deposited in this order over a first insulating layer 113. Subsequently, a resist mask 130 is formed to cover a capacitor region on the second electrode film 117A. Then, the second electrode film 117A, the ferroelectric film 116 and the first electrode film 115A are subjected to plasma etching using the resist mask 130, thereby patterning a ferroelectric capacitor 101.

However, the known memory device has a problem that, in a plasma etching process in the fabrication process thereof, an etching atmosphere containing a large amount of active species such as reactive free radicals creates, in an end portion of the ferroelectric film 116, a damaged region 116a which is damaged by the active species and can no longer have any property as a ferroelectric.

The damaged region 116a reduces the effective area of the ferroelectric capacitor 101. Specifically, the damaged region 116a inwardly extends several tens nm to several hundreds nm from the side face of the ferroelectric film 116. In the case where the area of the ferroelectric capacitor 101 is smaller than 1 μm², the reduction of effective area of the ferroelectric capacitor 101 cannot be neglected.

To suppress the occurrence of such a damaged region 116a, recovery annealing for recovering the damaged region 116a is performed after the formation of the ferroelectric capacitor 101. However, this annealing cannot eliminate the damaged region 116a completely.

In addition, the recovery annealing is performed at substantially the same temperature as the temperature at which the ferroelectric film 116 is crystallized. Accordingly, if the ferroelectric capacitor 101 is a stack of a plurality of layers, the recovery annealing needs to be performed on each of the layers, so that wiring provided in each of the layers disadvantageously deteriorates with heat. As a result, it is difficult to achieve a three-dimensional capacitor array in which the ferroelectric capacitor 101 is a stack of two or more layers.

Moreover, in the known fabrication method, the ferroelectric film 116 is formed on the entire surface of the first electrode film 115A by a sputtering method or a sol-gel method in the process step shown in FIG. 7A, and therefore, polycrystallization is essential. Accordingly, the crystal orientation of each individual grain in this polycrystalline film would take an arbitrary direction. As a result, a significant fraction of crystal grains would have little contribution to the polarization which can align along the applied electric field for polarization reversal.

### SUMMARY OF THE INVENTION

It is therefore an object of the present invention to prevent a damaged region from occurring in a capacitive film made of a ferroelectric. It is also an object of the present invention to prevent the polarization from appearing in different directions so as to control the crystal orientation.

In order to achieve the objects, the present invention provides a structure in which a ferroelectric film to be a capacitive film is selectively grown on a lower electrode.

Specifically, an inventive first memory device includes: a memory cell with a capacitor including a first electrode, a ferroelectric film and a second electrode, which are formed in this order over a substrate, wherein the ferroelectric film is selectively grown on the first electrode.

In the first memory device, if the first electrode has been patterned into a desired shape, etching for patterning the ferroelectric film is not needed because the ferroelectric film is selectively grown on the first electrode. As a result, no damaged region is created in the ferroelectric film to be a capacitive film of a capacitor, so that the capacitor can be downsized.

In the first memory device, the ferroelectric film is preferably made of a single crystal or a single domain. Then, there occurs no variation in polarization direction due to uniformization of the crystal orientations in polycrystallization, thus making it possible to control the crystal orientation of the ferroelectric film such that the polarization is at the maximum.

In the first memory device, the ferroelectric film is preferably grown to be self-organized by physical or chemical interaction between the ferroelectric film and the first electrode. Then, the ferroelectric film can be formed on the first electrode with an arbitrary planar shape, being self-aligned thereto.

In the first memory device, the ferroelectric film is preferably grown in a vapor phase or in a liquid phase.

In the first memory device, the capacitor is preferably connected to a selective switching device. Then, in the case where a plurality of memory cells are arranged in an array, a desired cell can be easily selected from among the memory cells.

In this case, the selective switching device is preferably formed on the substrate or between the substrate and the first electrode. Then, the density in the arrangement of the memory cells can be increased.

In this case, the selective switching device is preferably a transistor or a bidirectional diode. Then, if the selective switching device is a transistor, the memory cell array can be configured as an active matrix array. On the other hand, if the selective switching device is a bidirectional diode, the memory cell array can be configured as a simple matrix array.

An inventive second memory device includes: a first capacitor array layer including a plurality of capacitors each including a first electrode, a first ferroelectric film and a second electrode which are formed in this order over a substrate; and a second capacitor array layer including a plurality of capacitors each including a third electrode, a second ferroelectric film and a fourth electrode which are formed in this order as viewed from the substrate, the second capacitor array layer being formed over the first capacitor array layer with an insulating film interposed between the first and second capacitor array layers, wherein the first ferroelectric film is selectively grown on the first electrode, and the second ferroelectric film is selectively grown on the third electrode.

In the second memory device, the ferroelectric films included in the first capacitor array layer and the ferroelectric films included in the second capacitor array layer stacked on the first capacitor array layer are selectively grown on the first and third electrodes, respectively. Therefore, no etching for patterning the ferroelectric films is needed. As a result, no damaged region is created in the ferroelectric films to be capacitive films of the capacitors, so that the capacitors can be downsized. In addition, the capacitor array layers are disposed three-dimensionally, so that the density in the arrangement of memory cells can be increased.

In the second memory device, each of the first and second ferroelectric films is preferably made of a single crystal or a single domain.

In the second memory device, the first ferroelectric film is preferably grown to be self-organized by physical or chemical interaction between the first ferroelectric film and the first electrode, and the second ferroelectric film is grown to be self-organized by physical or chemical interaction between the second ferroelectric film and the third electrode.

In the second memory device, each of the first and second ferroelectric films is preferably grown in a vapor phase or in a liquid phase.

In the second memory device, the capacitors constituting the first and second capacitor array layers are preferably respectively connected to selective switching devices, thereby forming respective memory cells.

In this case, each of the selective switching devices is preferably formed on the substrate or between the substrate and the third electrode. Then, the wiring distance between the capacitor and the selective switching device in each of the memory cells is reduced.

In this case, the selective switching devices are preferably transistors or bidirectional diodes.

In this case, the selective switching devices respectively connected to the capacitors constituting the second capacitor array layer are preferably formed in the second capacitor array layer.

In this case, the selective switching devices formed in the second capacitor array layer are preferably thin film transistors or bidirectional diodes.

In this case, means for electrically connecting the memory cells included in the second capacitor array layer to one another is preferably provided between the first and second capacitor array layers or on the second capacitor array layer. Then, the density in the memory cell array in which memory cells are arranged three-dimensionally can be further increased.

In this case, means for electrically connecting the memory cells included in the first capacitor array layer to the memory cells included in the second capacitor array layer is preferably provided between the first and second capacitor array layers. Then, the density in the memory cells in which memory cells are arranged three-dimensionally can be further increased.

### BRIEF DESCRIPTION OF THE DRAWINGS

FIG. 1 is a cross-sectional view showing a structure of a memory cell array which is a main portion of a memory device according to a first embodiment of the present invention.

FIGS. 2A and 2B are cross-sectional views schematically showing respective process steps of a method for forming capacitive films of capacitors constituting the memory device of the first embodiment.

FIG. 3 is a graph for comparing the hysteresis characteristics of capacitors constituting the memory device of the first embodiment to the hysteresis characteristics of known capacitors.

FIG. 4 is a cross-sectional view showing a structure of a three-dimensional memory array which is a main portion of a memory device according to a second embodiment of the present invention.

FIG. 5 is a circuit diagram showing a known memory device whose memory cells include ferroelectric capacitors.

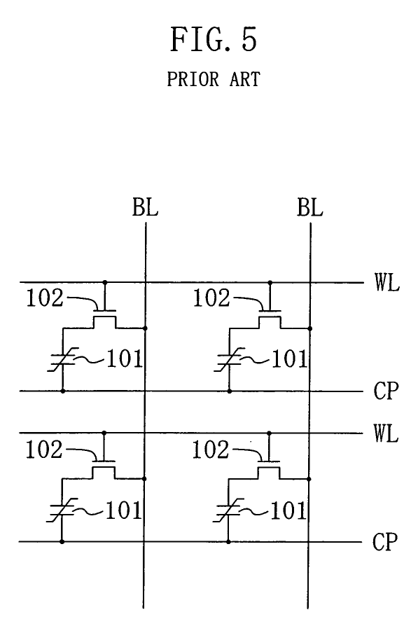

FIG. 6 is a cross-sectional view showing a structure of the known memory device whose memory cells include the ferroelectric capacitors.

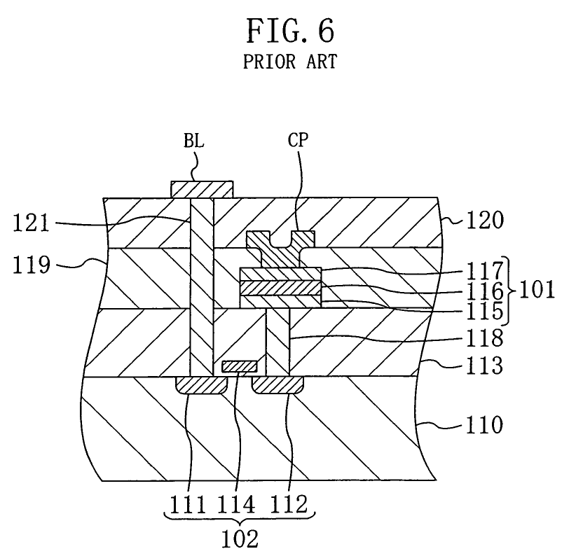

FIGS. 7A through 7C are cross-sectional views showing respective process steps of a method for forming the known ferroelectric capacitors.

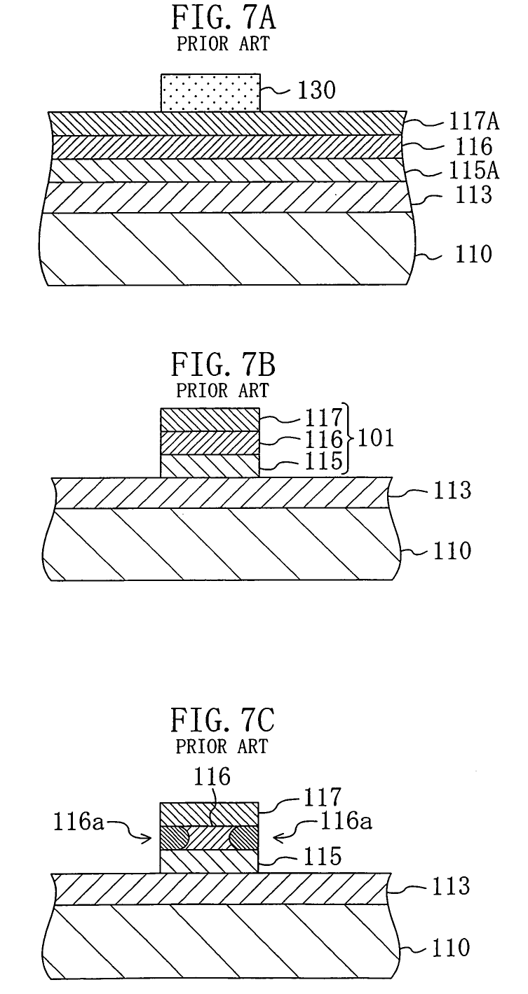

### DESCRIPTION OF THE PREFERRED EMBODIMENTS

### Embodiment 1

A first embodiment of the present invention will be described with reference to the drawings.

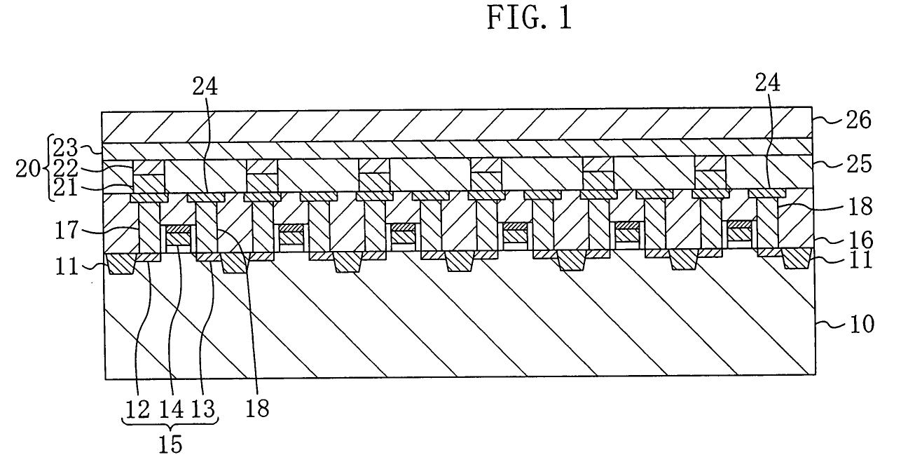

FIG. 1 shows a cross-sectional structure of a memory cell array which is a main portion of a memory device according to the first embodiment.

As shown in FIG. 1, a plurality of transistor regions divided by a plurality of transistor separation regions 11 made of silicon oxide are formed in an upper portion of a semiconductor substrate 10 made of, for example, silicon. In the transistor regions, selective transistors 15 serving as selective switching devices are respectively formed. Each of the selective transistors 15 includes: source and drain regions 12 and 13 formed to be spaced from each other; and a gate electrode 14 formed over the semiconductor substrate 10 between the source and drain regions 12 and 13.

A first insulating layer 16 is formed on the entire surface of the semiconductor substrate 10 including the transistor separation regions 11 and the gate electrodes 14. First contact plugs 17 are formed through the first insulating layer 16 to reach the respective source regions 12, while second contact plugs 18 are formed through the first insulating layer 16 to reach the respective drain regions 13.

Capacitors 20 are respectively formed over the first contact plugs 17. Each of the capacitors 20 includes: a lower electrode 21; a ferroelectric film 22 and an upper electrode 23 in this order from below. In this case, the ferroelectric films 22 of this embodiment are self-aligned to, i.e., are selectively grown on, the respective lower electrodes 21. The upper electrodes 23 also serve as a cell plate.

Bit lines 24 are formed in upper parts of the first insulating layer 16 to be electrically connected to the respective second contact plugs 18. A second insulating layer 25 is formed to fill in the gaps surrounded by the upper faces of the bit lines 24 and the respective sides of the lower electrodes 21 and the ferroelectric films 22. A third insulating layer 26 is formed on the upper electrode 23.

As an example of the structure of the capacitors 20, each of the lower electrodes 21 and the upper electrode 23 may be made of platinum (Pt) with a thickness of about 200 nm, and the ferroelectric films 22 may be made of SrBi₂Ta₂O₉ with a thickness of about 200 nm.

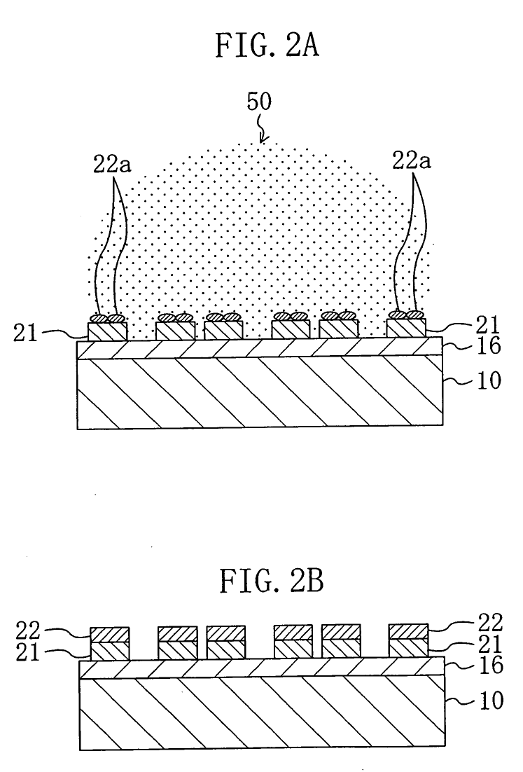

Hereinafter, a method for forming the capacitors 20 thus configured, especially the ferroelectric films, will be described with reference to FIGS. 2A and 2B.

Examples of methods for selectively growing the ferroelectric films 22 on the respective lower electrodes 21 include a method of forming ion clusters in a source gas for the ferroelectric films 22.

Firstly, a substrate 10 in which selective transistors (not shown) and a first insulating layer 16 have been formed is prepared. Although not shown, first and second contact plugs have been formed in the first insulating layer 16.

As shown in FIG. 2A, the substrate 10 is electrically grounded, and then is placed in a heating system (not shown) within a reaction chamber containing a source gas 50. The source gas 50 is a source gas for use in a metal organic chemical vapor deposition (MOCVD) process, for example. The source gas 50 that has been gasified into organic metal molecules is supplied to the reaction chamber.

In this case, the source gas 50 is passed through ionization apparatus including, for example, a corona tube (not shown) before being supplied to the reaction chamber. In this way, the source gas 50 is ionized to be positively charged ion clusters. The source gas 50 in the state of ion clusters is unstable with respect to energy, so that the source gas 50 tends to be stabilized by receiving electrons.

Accordingly, the source gas 50 in the state of ion clusters is stabilized by receiving electrons from the lower electrodes 21 that are electrically connected to the grounded substrate 10, and then the source gas 50 is thermally decomposed. In this way, ferroelectric formation films 22a start their selective growths on the respective lower electrodes 21. In this case, the process in which the ion clusters in the source gas 50 agglomerate on the lower electrodes 21 includes the case of self-organization, i.e., the case where the ion clusters agglomerate in the manner of self-assembly because of chemical affinity among identical molecules or clusters.

Therefore, if the lattice constant of crystals in the surfaces of the lower electrodes 21 is selected such that the lattice constant thereof is substantially the same as that of the ferroelectric formation films 22a, the ferroelectric formation films 22a are epitaxially grown on the respective lower electrodes 21 so that the resultant ferroelectric formation films 22a are made of a single crystal or a single domain.

The ion clusters in the material gas 50 do not agglomerate on the region of the first insulating layer 16 other than the lower electrodes 21. Accordingly, the ion clusters in the material gas 50 are not thermally decomposed in the region other than the region on the lower electrodes 21.

As a result, as shown in FIG. 2B, the ferroelectric formation films 21a grow only on the lower electrodes 21, thereby obtaining desired ferroelectric films 22.

The ferroelectric films 22 are preferably grown such that the ferroelectric films 22 are aligned to the respective lower electrodes 21 vertically to the surfaces of the lower electrodes 21 and have a single crystal structure as a crystal orientation which exhibits a relatively strong polarization.

Thereafter, although not shown, a second insulating layer 25 is deposited to cover the lower electrodes 21 and the ferroelectric films 22, and then is subjected to chemical mechanical polishing to be planarized such that the surfaces of the ferroelectric films 22 are exposed.

Subsequently, an upper electrode formation film is deposited by a vapor deposition process or a sputtering process over the second insulating layer 25 including the ferroelectric films 22. Thereafter, an upper electrode 23 having the shape of a cell plate is patterned out of the upper electrode formation film. Then, a third insulating layer 26 is formed to cover the upper electrode 23, thereby completing a memory device shown in FIG. 1.

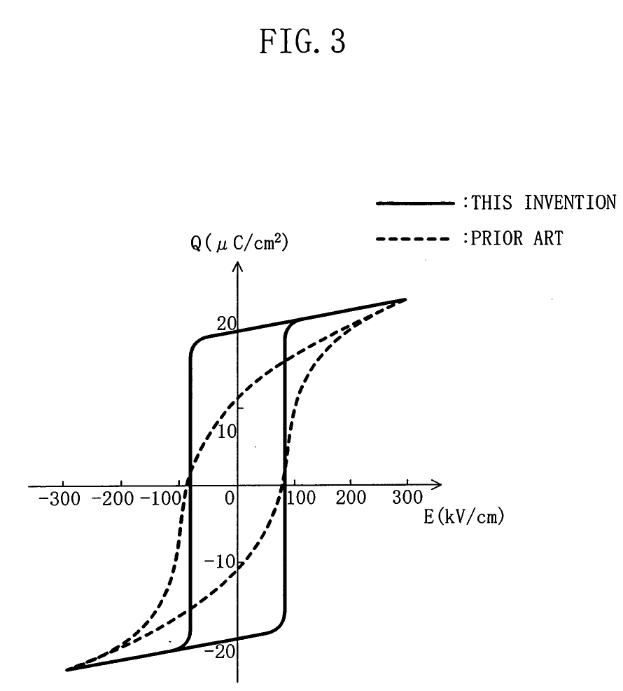

In the first embodiment, the ferroelectric films 22 serving as capacitive films for the capacitors 20 is made of a single crystal and has a crystal orientation in which an electric field is applied in the direction for exhibiting a relatively strong polarization. Accordingly, as shown in FIG. 3, hysteresis characteristics according to the present invention as indicated by the solid line are remarkably improved in response, as compared to those of polycrystalline ferroelectric films according to prior art as indicated by the broken line.

In addition, since the ferroelectric films 22 constituting the capacitors 20 are selectively formed on the respective lower electrodes 21, being self-aligned thereto, no etching for patterning is needed. Accordingly, no damage resulting from etching is created in the ferroelectric films 22, thus ensuring strong polarization. As a result, even downsized memory cells remarkably improves their characteristics in writing and reading data.

In this embodiment, a vapor phase process using the source gas 50 in the state of ion clusters is used for forming the ferroelectric films 22. However, the present invention is not limited to this process and may use a long throw sputtering process or a deposition process using a hydrothermal liquid phase.

### Embodiment 2

Hereinafter, a second embodiment of the present invention will be described with reference to the drawings.

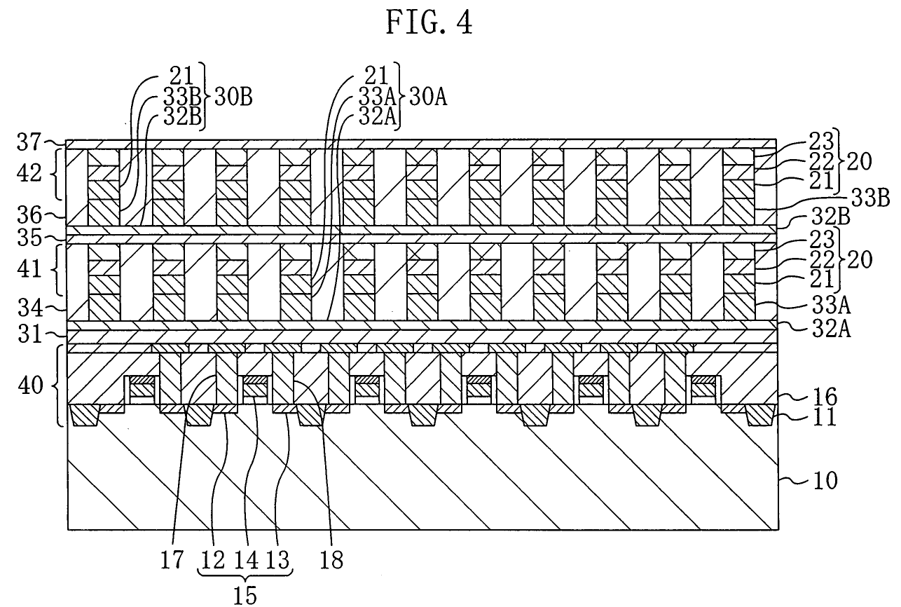

FIG. 4 shows a cross-sectional structure of a memory array which is a main portion of a memory device according to the second embodiment. In the second embodiment, memory cell array is configured by memory cells arranged three-dimensionally, i.e., stacked as two layers, so as to increase the density in the arrangement of the memory cells. In FIG. 4, each member already shown in FIG. 1 is identified by the same reference numeral and the description thereof will be omitted herein.

As shown in FIG. 4, a peripheral circuit portion 40 including selective transistors 15 and first and second capacitor array layers 41 and 42 each including a plurality of capacitors arranged in an array are formed in this order over a substrate 10.

A first cell plate line 32A is formed between the peripheral circuit portion 40 and the first capacitor array layer 41 with a second insulating layer 31 interposed between the first cell plate line 32A and the peripheral circuit portion 40.

A plurality of lower electrodes 21 are selectively formed over the first cell plate line 32A with first semiconductor thin films 33A of platinum with a thickness of, for example, about 200 nm interposed therebetween. In this way, the first cell plate line 32A, the first semiconductor thin films 33A and the lower electrodes 21 are connected in series, thereby forming bidirectional Schottky barrier diodes 30A of a metal-semiconductor-metal multilayer type.

Ferroelectric films 22 are selectively epitaxially grown only on the respective upper surfaces of the lower electrodes 21 by the same process as in the first embodiment.

Now, other members are described in accordance with the fabrication process. A third insulating layer 34 is formed to cover the ferroelectric films 22, and then is planarized by polishing until the surfaces of the ferroelectric films 22 are exposed. Thereafter, upper electrodes 23 are formed by a vapor deposition process or a sputtering process on the planarized surface of the second insulating layer 34 including the ferroelectric films 22, and then the upper electrodes 23 are patterned into desired shapes. Subsequently, a fourth insulating layer 35 is formed on the third insulating layer 34 to cover the upper electrodes 23, thereby completing a first capacitor array layer 41.

Then, after the upper surface of the fourth insulating layer 35 has been planarized, a second cell plate line 32B is formed on the fourth insulating layer 35. Thereafter, a second capacitor array layer 42 is formed on the second cell plate line 32B, in the same manner as for the first capacitor array layer 41.

Specifically, second semiconductor thin films 33B and lower electrodes 21 are stacked on the second cell plate line 32B, and then are patterned into desired shapes, thereby forming a plurality of second bidirectional Schottky barrier diodes 30B made of the second cell plate line 32B, the second semiconductor thin films 33B and the lower electrodes 21. Thereafter, in the manner described above, ferroelectric films 22 are selectively epitaxially grown only on the lower electrodes 21.

Subsequently, the gaps between the side surfaces of the second semiconductor thin films 33B, lower electrodes 21 and ferroelectric films 22 are filled with a fifth insulating layer 36, and then upper electrodes 23 are processed to connect to the respective ferroelectric films 22. Lastly, a sixth insulating layer 37 is formed on the surface of the fifth insulating layer 36 including the upper electrodes 23, thereby completing a second capacitor array layer 42.

In the second embodiment, with respect to the first capacitor array layer 41, for example, the first bidirectional Schottky barrier diodes 30A made up of the first cell plate line 32A, the first semiconductor thin films 33A and the lower electrodes 21 function as selective switching devices for respective memory cells.

Although not shown, a wiring portion where memory cells including the capacitors 20 arranged in the first capacitor array layer 41 are electrically connected to memory cells including the capacitors 20 arranged in the second capacitor array layer 42 is buried between the first and second capacitor array layers 41 and 42.

In the second embodiment, the capacitor array layer is made of two layers. However, the present invention is not limited to this specific embodiment and three or more layers may constitute the capacitor array layer. In this way, it is possible to arrange the memory cell array three-dimensionally without forming any damaged region in a capacitor film made of a ferroelectric, thus downsizing memory cells as well as increasing the density in the arrangement of the memory cells.

Instead of the second bidirectional Schottky barrier diodes 30B, a thin film transistor may be used.

1-18. (canceled)

19. A fabrication method of a memory device comprising:
a step of forming a memory cell with a capacitor including;
a sub-step of forming a first electrode on a substrate,
a sub-step of forming a ferroelectric film which is selectively grown on the first electrode, and
a sub-step of forming a second electrode on the ferroelectric film.

20. The fabrication method of claim 19, wherein the ferroelectric film is made of a single crystal or a single domain.

21. The fabrication method of claim 19, wherein a lattice constant of crystals of the first electrode is substantially the same as that of the ferroelectric film.

22. The fabrication method of claim 19, wherein the ferroelectric film is grown to be self-organized by physical or chemical interaction between the ferroelectric film and the first electrode.

23. The fabrication method of claim 22, wherein the ferroelectric film is grown in a vapor phase or in a liquid phase.

24. The fabrication method of claim 22 further comprising:
a step of forming a selective switching device to be connected to the capacitor.

25. The fabrication method of claim 24, wherein the selective switching device is formed on the substrate or between the substrate and the first electrode.

26. The fabrication method of claim 24, wherein the selective switching device is a transistor or a bidirectional diode.

27. A fabrication method of a memory device comprising:
a step of forming a first capacitor array layer including a plurality of capacitors; and
a step of forming a second capacitor array layer including a plurality of capacitors over the first capacitor array layer with an insulating film interposed between the first and the second capacitor array layers;
wherein the step of forming the first capacitor array layer includes;
a sub-step of forming a first electrode on a substrate,
a sub-step of forming a first ferroelectric film which is selectively grown on the first electrode, and
a sub-step of forming a second electrode on the first ferroelectric film; and
the step of forming the second capacitor array layer includes;
a sub-step of forming a third electrode on the substrate,
a sub-step of forming a second ferroelectric film which is selectively grown on the third electrode, and
a sub-step of forming a fourth electrode on the second ferroelectric film.

28. The fabrication method of claim 27, wherein each of the first and the second ferroelectric films is made of a single crystal or a single domain.

29. The fabrication method of claim 27, wherein a lattice constant of crystals of the first electrode is substantially the same as that of the first ferroelectric film and a lattice constant of crystals of the third electrode is substantially the same as that of the second ferroelectric film.

30. The fabrication method of claim 27, wherein the first ferroelectric film is grown to be self-organized by physical or chemical interaction between the first ferroelectric film and the first electrode, and
the second ferroelectric film is grown to be self-organized by physical or chemical interaction between the second ferroelectric film and the third electrode.

31. The fabrication method of claim 27, wherein each of the first and the second ferroelectric films is grown in a vapor phase or in a liquid phase.

32. The fabrication method of claim 27 further comprising:
a step of forming selective switching devices to be respectively connected to the capacitors constituting the first and the second capacitor array layers, thereby forming respective memory cells.

33. The fabrication method of claim 32, wherein each of the selective switching devices is formed on the substrate or between the substrate and the third electrode.

34. The fabrication method of claim 32, wherein the selective switching devices are transistors or bidirectional diodes.

35. The fabrication method of claim 32, wherein the selective switching devices respectively connected to the capacitors constituting the second capacitor array layer are formed in the second capacitor array layer.

36. The fabrication method of claim 32, wherein the selective switching devices formed in the second capacitor array layer are thin film transistors or bidirectional diodes.

37. The fabrication method of claim 32 further comprising:
a step of forming means for electrically connecting the memory cells included in the second capacitor array layer to one another between the first and the second capacitor array layers or on the second capacitor array layer.

38. The fabrication method of claim 32 further comprising:
a step of forming means for electrically connecting the memory cells included in the first capacitor array layer to the memory cells included in the second capacitor array layer between the first and the second capacitor array layers.
